(19) United States
(12) Patent Application Publication
(10) Pub. No.: US 2009/0013230 A1
(43) Pub. Date: Jan. 8, 2009

(54) CIRCUIT ARRANGEMENT AND METHOD OF TESTING AND/OR DIAGNOSING THE SAME

(75) Inventors: Andreas Glowatz, Heidenau (DE); Friedrich Hapke, Winsen/Luhe (DE); Stefan Otto Eichenberger, Kleve (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/813,428

(22) PCT Filed: Dec. 19, 2005
(86) PCT No.: PCT/IB2005/054297

§ 371 Date: Apr. 29, 2008

(30) Foreign Application Priority Data
Jan. 4, 2005 (EP) 05100013.1

(51) Int. Cl. G01R 31/3177; G06F 11/25

(52) U.S. Cl. 714/738; 714/E11.155

(57) ABSTRACT

To further develop a circuit arrangement (100; 100′), and in particular an application circuit, that is arranged to generate at least one test pattern, and a method of testing and/or diagnosing the circuit arrangement (100; 100′) in such a way that reliable fault detection is ensured, it is proposed that the test pattern be remodelable and/or extendable into at least one presettable and/or deterministic test vector by means of at least one test pattern remodeling/extending element (10, 12, 14; 10′, 12′, 14′, and in that—the at least one test pattern remodeling/extending element (10, 12, 14; 10′, 12′, 14′) is arranged, and in particular is inserted, upstream of at least one, and in particular upstream of each, branch point (52, 54, 56) on the at least one signal path (50).

The present invention relates to a circuit arrangement, and in particular an application circuit, that is arranged to generate at least one test pattern (see printed publication DE 102 01 554 A1 from the prior art).

The present invention also relates to a method of testing and/or diagnosing at least one circuit arrangement, and in particular at least one application circuit.

A major aspect of the production of integrated circuits is represented by the testing of such circuits. Even during the design of an integrated circuit, it is very important for thought to be given to its testability. The aim of reflections of this kind is for test methods to be made available by means of which an integrated component or an integrated assembly can be tested for its ability to operate correctly.

A standard method of testing for the production testing of digital circuits of this kind comprises applying test signals (so-called test patterns) to the inputs of the circuit and comparing the output signals obtained as a result with the signals from a circuit that is free of any faults or defects. If a discrepancy is found between the signals measured and those expected, it can be assumed that the circuit tested contains at least one fault or defect and is therefore unfit for use.

To a very large degree, test patterns for hardware verification are nowadays generated by automated testing tools (so-called automatic test pattern generators). For detecting defects in circuits, ATPG (automatic test pattern generation) is a standard method of generating input vectors; hence what are used in this case are programs for the automatic generation of test patterns.

Algorithms are used to generate the test patterns in the programs for ATPG and these employ, amongst other things, what is termed the “(single) stuck-at” fault model. In this fault model, it is assumed that the faulty circuit behaves as if a given circuit node were permanently wired to logic 1 or logic 0.

Hence a “stuck-at” defect exists if a line or a signal in the circuit incorrectly always assumes a logic value of 1 (“stuck-at-1”) or a logic value of 0 (“stuck-at-0”). Physical causes of stuck-at defects of this kind may for example be short circuits to voltages or short circuits to ground.

One of the principal differences between the different algorithms lies in the fact that the algorithms in question assume different locations within the circuit to be possible causes of faults. The quality of an algorithm is then determined by how far these assumed locations cover the possible locations of actual physical defects.

Traditionally, what have been assumed as faults and fault locations have been the following:

stuck-at-0 faults or stuck-at-1 faults at inputs and outputs of circuit elements,

delay faults at inputs and outputs of circuit elements,

open faults at inputs and outputs of circuit elements, and/or

short circuits between adjacent electrical lines.

Because it has been recognized by experiment that such approaches are not good enough to ensure good product quality with today's highly integrated circuits, certain generators have gone over to introducing what is termed an “N detect” method. In the N detect method, the generator is instructed to detect each fault or defect a plurality of times, namely N times.

This is done in obedience to the principle of probability: because the fault models do not completely cover the defects that occur, a plurality of attempts are made to detect defects using different test patterns, which means that there is a high probability of the defect manifesting itself at least once, thus enabling the defective circuit to be recognized. This method gives a measurable improvement in the coverage of the testing, but it does not allow any actual qualitative statement to be made.

The description of the circuit that is used for the test pattern generator is usually based on a grid model that corresponds to the logic behavior of the actual circuit.

In printed publications DE 100 38 327 A1, DE 101 10 177 A1, DE 102 01 554 A1 and DE 102 09 078 A1 from the prior art, there are disclosed respective possible ways of implementing testing arrangements of this kind. From printed publication U.S. Pat. No. 6,721,914 B2 from the prior art, there is also known a general method of fault detection for a printed circuit.

Reference should also be made to

printed publication U.S. Pat. No. 6,202,181 B1 from the prior art, in which it is proposed that the diagnosis of bridging faults be improved by means of a failure analysis function, and

printed publication US 2004/0133833 A1 from the prior art, in which it is proposed that a minimum number of test patterns be selected from manually generated functional verification patterns. However, no account is taken in these printed publications of layout-related data; it is therefore not possible for layout-related faults to be detected.

Finally, it also has to be borne in mind in this connection that a distinguishing feature of modern-day circuits is increasingly complex wiring structures, in which stuck-at faults, short circuits, delay faults or open faults can occur anywhere along the lines—from the driver to the different receiving components.

Because the known circuit models and the known methods of test pattern detection are matched only to the logic behavior of the actual circuit, faults in the wiring elements cannot be covered. For this reason it is necessary for such conventional testing circuits, and in particular the conventional fault models and fault location assumptions, to be improved and extended.

Taking as a basis the disadvantages and shortcomings that have been described above and with due allowance for the prior art that has been outlined, it is an object of the present invention to further develop a circuit arrangement of the kind specified in the opening paragraph above and a method of the kind specified in the second paragraph above in such a way that reliable fault detection is ensured and in particular that

stuck-at-0 faults and stuck-at-1 faults can be detected not only at inputs or outputs of circuit elements but also at wiring elements,

delay faults can be detected not only at inputs or outputs of circuit elements but also at wiring elements,

open faults can be detected not only at inputs or outputs of circuit elements but also at wiring elements, and

short circuits between adjacent electrical lines can be detected.

This object is achieved by a circuit arrangement having the features specified in claim 1 and by a method having the features specified in claim 5. Advantageous embodiments and useful refinements are characterized in the respective sets of dependent claims.

The present invention is thus based on the principle of describing the logic behavior of the circuit and its behavior in the event of layout-related faults. A circuit model of this kind makes it possible for the requisite test patterns by which the above-mentioned layout-related production faults can be detected to be calculated with at least one test pattern generator.

For this purpose, there is made available a circuit having an application circuit to be tested and/or diagnosed and having additional logic, the said additional logic being intended for testing and/or diagnosing the application circuit and having an arrangement for generating deterministic test patterns for detecting wiring faults.

These deterministic test patterns are fed to the application circuit for testing purposes, and the quality of the test patterns can be appreciably increased specifically for integrated circuits having complex wiring structures.

In this way, in a particularly advantageous embodiment of the present invention, new fault signatures can be calculated by the additional logic, thus improving the accuracy with which these fault signatures, and also all the other production faults, can be located.

The fault detection, and also the diagnostic resolution, is thus significantly improved in respect of stuck-at faults and in respect of open faults and in respect of delay faults.

By way of example, the procedure followed in the method according to the present invention may be of the following form:

[i] remodeling of the logic (description) while taking account of the layout description, after, as an option, at least one logic (description) and at least one layout description have previously been generated,
[ii] generation, and in particular remodeling and/or extension, of at least one test pattern using the remodeled logic (description) from [i],
[iii] generation of at least one new fault signature using the remodeled logic (description) from [i] and the remodeled and/or extended test pattern from [ii].

In accordance with the teaching of the present invention, at least one test pattern remodeling/extending element and/or test pattern amending or modifying element, in the form of, for example, at least one buffer or in the form of at least one fan-out object, is inserted in the circuit of the test pattern generator whenever there is a signal branch or a signal branch point present in the actual layout.

The essential advantages of the present invention are that

the quality of the test patterns for highly complex circuits is appreciably increased,

the fault location for production faults can be carried out with appreciably greater accuracy,

no additional hardware is required on the actual IC (integrated circuit),

the test pattern generation can be carried out more efficiently by using the union of sets of stuck-at-0 faults and stuck-at-1 faults in the so-called N detect method,

existing test pattern generators can be used because at least one additional test pattern remodeling/extending element, and in particular at least one additional one fan-out element, is simply fitted in the circuit for the generator.

Preferably, layout data is explicitly used for the generation of appropriate test patterns, as a result of which fault detection is improved. In conjunction with the corresponding test patterns, this method of using layout data also improves the diagnostic resolution.

In a useful embodiment of the present invention, an optimum compilation of test patterns is calculated by means of at least one ATPG (automatic test pattern generator). Also, the test patterns required are preferably generated on the basis of layout conditions.

Finally, the present invention relates to the use of at least one circuit arrangement of the kind described above, and/or of a method of the kind described above, for testing and/or diagnosis, and in particular

for tracing and/or detecting faults, such as production faults for example, in the form of, say, wiring faults, in the logic part of the circuit arrangement and/or

for calculating at least one new fault signature, as a result of which the accuracy with which this fault signature and/or other production faults can be located is improved.

The present invention thus relates to the field of application of testing technology for integrated circuits (ICs), of their design for testability (DfT), of their computer aided design (CAD) and of their computer aided testing (CAT); the present invention relates in particular to the qualitative improvement of the production testing of integrated circuits and to a more effective possible way of tracing production-related faults.

The integrated circuit arrangement described above, the method described above and also the use described above increase the quality of the testing not only in respect of the stuck-at fault model but also in respect of open faults and in respect of delay faults.

Because, in the case of open faults, the state of the floating part is determined by (more or less) random factors, such as, say, the electrical state of the surrounding circuitry, it makes perfectly good sense, even after the modification of the network listing that has been described, for faults to be detected by the so-called N detect method.

As has already been discussed above, there are various possible ways of embodying and developing the teaching of the present invention in an advantageous manner. For this purpose, on the one hand reference should be made to the claims dependent on claim 1 and claim 5. On the other hand, these and other aspects of the invention are apparent from and will be elucidated with reference to the embodiments described hereinafter.

In the drawings:

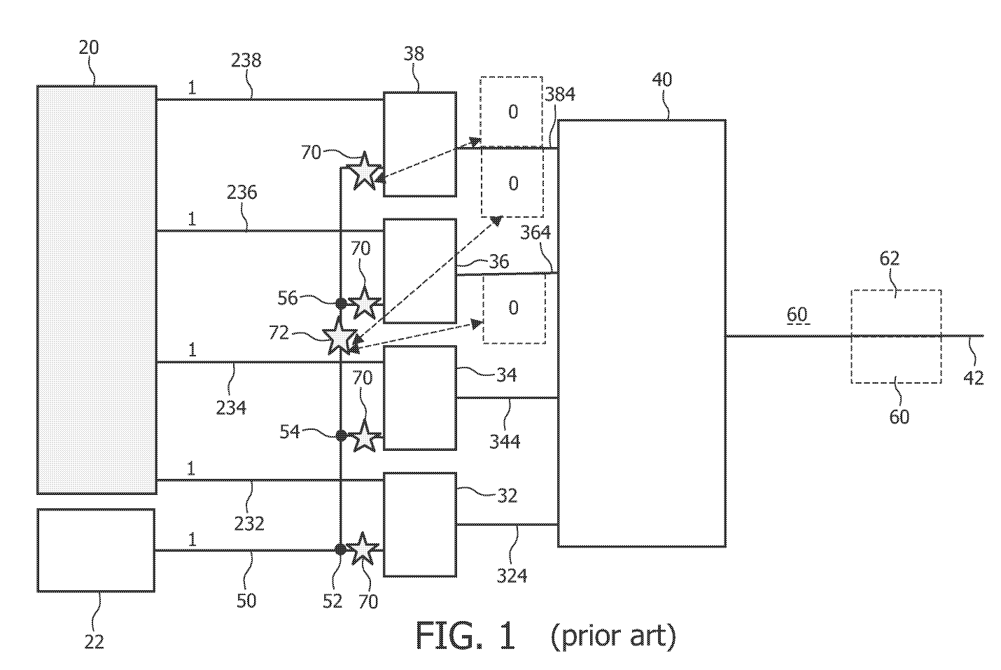

FIG. 1 is a schematic block circuit diagram of an embodiment of prior art integrated circuit arrangement that operates in a conventional manner.

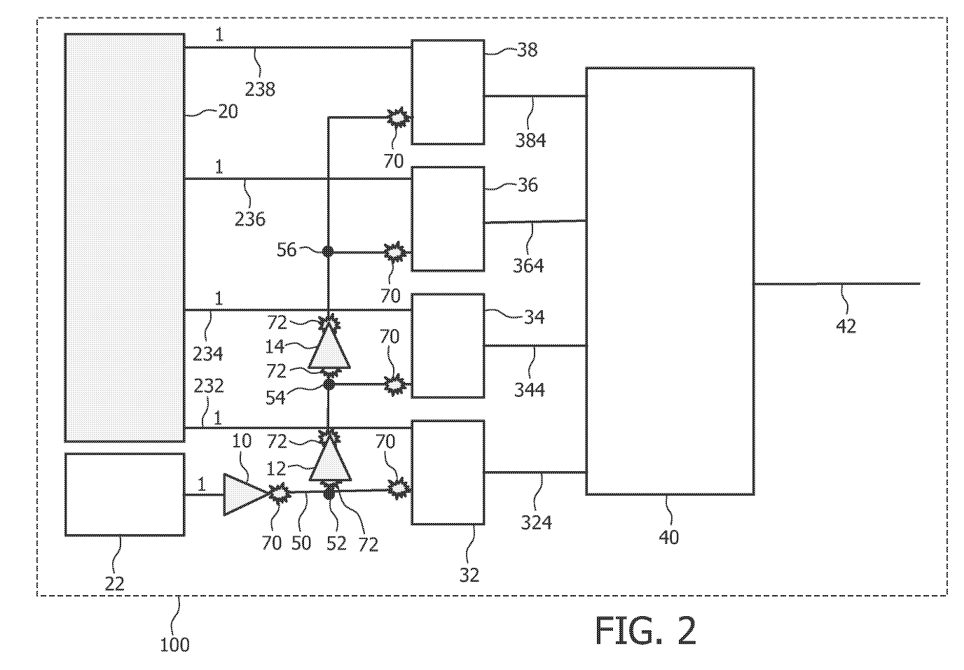

FIG. 2 is a schematic block circuit diagram of a first embodiment of integrated circuit arrangement according to the present invention that operates by the method according to the present invention, and

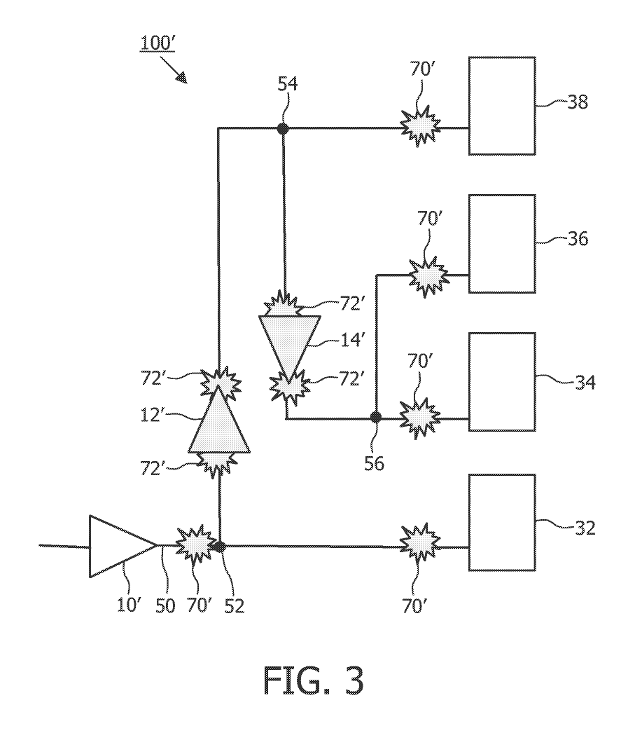

FIG. 3 is a schematic detail of a block circuit diagram of a second embodiment of integrated circuit arrangement according to the present invention that operates by the method according to the present invention.

Arrangements, elements or features that are the same or similar are given the same reference numerals in FIGS. 1 to 3.

To avoid excessive repetition, the following elucidation relating to the embodiments, features and advantages of the present invention (except where they are specified elsewhere) relates both to the prior art circuit arrangement that is shown in FIG. 1 and to the circuit arrangement 100 according to the present invention that is shown in FIG. 2, and also to the circuit arrangement 100′ according to the present invention that is shown in FIG. 3.

FIGS. 1 and 2 are schematic block circuit diagrams of respective integrated circuit arrangements (=integrated circuits or ICs; reference numeral 100 in FIG. 2); this circuit arrangement is in each case an application circuit having a test module for generating test patterns.

In order now to ensure successful fault detection in the application circuit 100, in which

stuck-at-0 faults and stuck-at-1 faults are detected not only at inputs or outputs of circuit elements but also at wiring elements,

delay faults are detected not only at inputs or outputs of circuit elements but also at wiring elements,

open faults are detected not only at inputs or outputs of circuit elements but also at wiring elements, and

short circuits between adjacent electrical lines are detected,

the approach to a solution that is adopted in the circuit 100 according to the present invention that is shown in FIG. 2 comprises changing the fault that is identified by reference numeral 72 in FIG. 1 (=the prior art) into a fault such as can be covered by computing rules that are known per se for generating test patterns (so-called ATPG (automatic test pattern generator) algorithms).

The procedure adopted for this purpose is as follows:

a detailed layout analysis is made of the wiring structure,
upstream of each signal branch 52, 54, 56 in the layout, the circuit is modified in such a way that it contains additional respective buffers 10, 12 and 14;
the test pattern generation is then applied to the circuit 100 that has been modified in this way.

This will be described below by means of a description that makes a comparison with the conventional prior art approach:

For this purpose, it will be assumed that the faulty circuit shown in FIGS. 1 and 2 is affected by one of the following defects or faults 70:

stuck-at-0/1 faults at inputs and/or outputs of circuit elements,

delay faults at inputs and/or outputs of circuit elements,

open faults at inputs and/or outputs of circuit elements,

short circuits between adjacent electrical lines.

In the integrated circuit shown in FIG. 1 (=prior art), the test pattern generation is not good enough for the stuck-at-0 fault (=reference numeral 72, shown upstream of the branch 56 in the layout) if only a logic circuit model is used. The circuit shown by way of example in FIG. 1 has four inputs and one output.

The output corresponds to the parity (“even”->reference numeral 60; “odd”->reference numeral 62) of the number of inputs that are at logic 1. If however the enable input is at logic 0, the other inputs are ignored.

The known or conventional methods of generating test patterns accept only the stuck-at defects that are denoted by reference numeral 70 in FIG. 1 and generate corresponding test patterns. The pattern shown in FIG. 1, namely all inputs at logic 1, tests all the faults denoted by reference numeral 70 simultaneously, because it is assumed that only one fault at a time is present in the circuit. Under these assumptions it is therefore enough, conventionally (=FIG. 1), for only this one test pattern to be applied for the stuck-at defects 70.

It can however be seen that a fault that is denoted by reference numeral 72 in FIG. 1 will not be found because, in the model described that is shown in FIG. 1, a fault 72 of this kind represents the simultaneous presence of two faults 70. Because of the increasing complexity of the wiring structure and, as a result thereof, the increasing probability of faults 72 occurring, it is important for test patterns to be generated for these latter too.

For this purpose, in accordance with the teaching of the present invention, there are connected in the embodiment shown in FIG. 2 three additional, test pattern remodeling/extending elements that are shown in FIG. 2 as buffer units 10, 12, 14. The passage of signals from a second (application) sub-circuit 22 of the circuit arrangement 100 to further (application) sub-circuits elements 32, 34, 36, 38 of the circuit arrangement 100 takes place via corresponding signal paths in the form of branched connections 50.

In the embodiment shown in FIG. 2, the sub-circuits 32, 34, 36, 38 are each arranged, by way of example, to be logic elements that are in the form of logic AND gates and that are connected in parallel with one another; these logic elements 32, 24, 36, 38 may however also each be in the form of

at least one logic NAND gate,

at least one logic NOR gate,

at least one logic NOT gate,

at least one logic OR gate,

at least one logic exclusive-OR gate.

Arranged at, and specifically upstream of, each branch point 52, 54 or 56 in the layout of the signals paths 50 are respective test pattern remodeling/extending elements 10, 12 and 14, namely

a first test pattern remodeling/extending element 10 upstream of the first branch point 52 on the corresponding signal path 50,

a second test pattern remodeling/extending element 12 upstream of the second branch point 54 on the corresponding signal path 50, and

a third test pattern remodeling/extending element 14 upstream of the third branch point 56 on the corresponding signal path 50.

Whereas the faults that are denoted by reference numeral 70 in FIG. 2 can be covered, i.e. embraced, even by a conventional method of generating test patterns (see FIG. 1), what is effected in accordance with the invention by the arranging of the buffers 10, 12, 14 is that the faults that are denoted by the reference numeral 72 are also provided with coverage in tests by the method that is described here. In place of the buffer units 10, 12, 14, one or more fan-out units may also be provided.

As can also be seen from FIG. 2, the further sub-circuits 32, 34, 36, 38 have connected upstream of them any desired first sub-circuit 20 (=any desired module having four outputs) of the application circuit 100; in detail

the first (upper in FIG. 2) input terminal of the first logic element 32 has a connection 232 to the first output terminal of the first application circuit 20,

the first (upper in FIG. 2) input terminal of the second logic element 34 has a connection 234 to the second output terminal of the first application sub-circuit 20,

the first (upper in FIG. 2) input terminal of the third logic element 36 has a connection 236 to the third output terminal of the first application sub-circuit 20, and

the first (upper in FIG. 2) input terminal of the fourth logic element 38 has a connection 238 to the fourth output terminal of the first application sub-circuit 20.

As can finally be seen from FIG. 2, the sub-circuits 32, 34, 36, 38 are connected on the downstream side to a third sub-circuit 40 (such as, for example, a parity checker having four inputs); in detail

the output terminal of the first logic element 32 has a connection 324 to the first input terminal of the third application sub-circuit 40,

the output terminal of the second logic element 34 has a connection 344 to the second input terminal of the third application sub-circuit 40,

the output terminal of the third logic element 36 has a connection 364 to the third input terminal of the third application sub-circuit 40, and

the output terminal of the fourth logic element 38 has a connection 384 to the fourth input terminal of the third application sub-circuit 40.

The output of the third application sub-circuit 40 has a connection 42
to a primary output of the circuit arrangement 100 or
to an input of a further application sub-circuit.

In the first embodiment (=circuit arrangement 100) of the present invention that is shown in FIG. 2, it is assumed for the sake of simplicity that the physical layout does in fact correspond to the network plan (as drawn). Should this not be the case, then it is the physical layout that is crucial.

Accordingly, in the case of the second embodiment of the present invention (=circuit arrangement 100′), there is shown in FIG. 3 a wiring sequence that differs from the sequence in the first embodiment shown in FIG. 2, and the corresponding consequences that this has on the inserted buffers 10′, 12′, 14′ and the faults 70′, 72′.

The detection of the faults that are denoted by reference numeral 72 in FIG. 2 and of the faults that are denoted by reference numeral 72′ in FIG. 3 can be performed considerably more efficiently if the union of sets of stuck-at-0 faults (what are termed SAO faults) and stuck-at-1 faults (what are termed SA1 faults) is detected N times at the virtual buffers rather than the corresponding test patterns for stuck-at-0 faults and stuck-at-1 faults being generated separately (N being a user-definable quality parameter that is to be termed the depth of detection).

By means of this N detect method, the generator is instructed to detect each defect a plurality of times, namely N times. Because the fault models do not fully cover the existing faults 70, 72 (see FIG. 2) or 70′, 72′ (see FIG. 3), the principle of probability is applied, i.e. a plurality of attempts are made to detect faults 70, 72 (see FIG. 2) or 70′, 72′ (see FIG. 3) with different test patterns, which means that there is a high probability that the fault 70, 72 (see FIG. 2) or 70′, 72′ (see FIG. 3) will manifest itself at least once and the faulty application circuit 100 or 100′ can thus be recognized.

All in all, what is achieved with the present invention is that the circuit 100 shown in FIG. 2 or the circuit 100′ shown in FIG. 3 defines logic behavior and behavior in the event of layout-related faults and the test pattern generator will thus take these additional faults into account and will be able to generate test patterns that are required.

### LIST OF REFERENCE NUMERALS

100 Circuit arrangement, in particular an application circuit, such as, for example, a sub-circuit of an integrated circuit (first embodiment of the present invention; see FIG. 2)
100′ Circuit arrangement, in particular an application circuit, such as, for example, a sub-circuit of an integrated circuit (second embodiment of the present invention; see FIG. 3)
10 First test pattern remodeling/extending element, in particular first buffer unit or first fan-out unit (first embodiment of the present invention; see FIG. 2)
10′ First test pattern remodeling/extending element, in particular first buffer unit or first fan-out unit (second embodiment of the present invention; see FIG. 3)
12 Further, and in particular second, test pattern remodeling/extending element, such as, for example, second buffer unit or second fan-out unit (first embodiment of the present invention; see FIG. 2)
12′ Further, and in particular second, test pattern remodeling/extending element, such as, for example, second buffer unit or second fan-out unit (second embodiment of the present invention; see FIG. 3)
14 Further, and in particular third, test pattern remodeling/extending element, such as, for example, third buffer unit or third fan-out unit (first embodiment of the present invention; see FIG. 2)
14′ Further, and in particular third, test pattern remodeling/extending element, such as, for example, third buffer unit or third fan-out unit (second embodiment of the present invention; see FIG. 3)
20 First sub-circuit, and in particular first application sub-circuit, of the circuit arrangement 100
22 Second sub-circuit, and in particular second application sub-circuit, of the circuit arrangement 100
232 Connection of the first output terminal of the first sub-circuit 20 to the first input terminal of the first logic element 32
234 Connection of the second output terminal of the first sub-circuit 20 to the first input terminal of the second logic element 34
236 Connection of the third output terminal of the first sub-circuit 20 to the first input terminal of the third logic element 36
238 Connection of the fourth output terminal of the first sub-circuit 20 to the first input terminal of the fourth logic element 38
32 First logic element, in particular first logic gate, such as, for example, first AND element, first NAND element, first NOR element, first NOT element, first OR element, first exclusive-OR element, or the like
324 Connection of the output terminal of the first logic element 32 to the first input terminal of the third sub-circuit 40
34 Second logic element, in particular second logic gate, such as, for example, second AND element, second NAND element, second NOR element, second NOT element, second OR element, second exclusive-OR element, or the like
344 Connection of the output terminal of the second logic element 34 to the second input terminal of the third sub-circuit 40
36 Third logic element, in particular third logic gate, such as, for example, third AND element, third NAND element, third NOR element, third NOT element, third OR element, third exclusive-OR element, or the like
364 Connection of the output terminal of the third logic element 36 to the third input terminal of the third sub-circuit 40
38 Fourth logic element, in particular fourth logic gate, such as, for example, fourth AND element, fourth NAND element, fourth NOR element, fourth NOT element, fourth OR element, fourth exclusive-OR element, or the like
384 Connection of the output terminal of the fourth logic element 38 to the fourth input terminal of the third sub-circuit 40
40 Third sub-circuit, in particular third application sub-circuit, such as a parity checker for example, of the circuit arrangement 100
42 Connection of the output terminal of the third sub-circuit 40 to a primary output of the circuit arrangement 100 or to an input of a further sub-circuit and in particular of a further application sub-circuit
50 Signal path, in particular a branched connection of the first test pattern remodeling/extending element 10 to the logic elements 32, 34, 36, 38
52 First branch point on the signal path 50
54 Second branch point on the signal path 50
56 Third branch point on the signal path 50
60 “Even” parity (state)
62 “Odd” parity (state)
70 Fault or defect, in particular a stuck-at fault (first embodiment of the present invention; see FIG. 2)
70′ Fault or defect, in particular a stuck-at fault (second embodiment of the present invention; see FIG. 3)
72 Additional fault or defect, in particular an additional stuck-at fault (first embodiment of the present invention; see FIG. 2)
72′ Fault or defect, in particular an additional stuck-at fault (second embodiment of the present invention; see FIG. 3)
N Depth of detection (in the form of a user-definable quality parameter)

1. A circuit arrangement, comprising an application circuit having at least one branch point and at least one signal path, arranged for the generation of at least one test pattern, having
at least one test pattern remodeling/extending element capable of remodeling or extending said test pattern into at least one presettable or deterministic test vector and
in that the at least one test pattern remodeling/extending element is inserted, upstream of at least one, branch point on at least one signal path.

2. A circuit arrangement as claimed in claim 1, characterized in that the test pattern remodeling/extending element is
at least one first buffer unit or
at least one first fan-out unit.

3. A circuit arrangement as claimed in claim 1, characterized in that at least one respective fault signature can be calculated for the test signal able to be fed to the given test pattern remodeling/extending element.

4. A circuit arrangement as claimed in claim 1, characterized in that the test pattern remodeling/extending element has either
at least one sub-circuit, connected upstream of it
at least one sub-circuit, connected downstream of it.

5. A circuit arrangement comprising, at least one application circuit having at least one test pattern remodeling one extending element, and, characterized in that at least one respective fault signature can be calculated for a test signal to be fed to the at least one test pattern remodeling/extending element.

6. A method of testing and diagnosing at least one circuit arrangement having at least one logic description and at least one layout description comprising:
[i] remodeling of at least one logic description while taking account of at least one layout description,
[ii] generation, and in particular remodeling or extension, of at least one test pattern by means of the logic description remodeled in step [i],
[iii] generation of the least one respective fault signature
by means of the logic description remodeled in step [i] and
by means of the test pattern generated in step [ii].

7. A method as claimed in claim 6, characterized in that
[a] the logic behavior of the circuit arrangement when faulted or
[b] the behavior of the circuit arrangement in the event of layout-related faults is analyzed and is taken into account when generating the test pattern.

8. A method as claimed in claim 7, characterized in that, in case [b],
the wiring structure is analyzed in respect of its layout,
the circuit arrangement is modified at least one, and in particular upstream of each, branch point on the at least one signal path in such a way that at least one test pattern remodeling/extending element, and in particular at least one buffer unit or at least one fan-out unit, is inserted and
the generation of the test pattern is applied to the circuit arrangement that has been modified in this way.

9. A method as claimed in claim 1, characterized in that the test pattern is calculated by means of at least one ATPG Automatic Test Pattern Generator.

10. (canceled)
